(19) United States
(12) Patent Application Publication
(10) Pub. No.: US 2026/0056249 A1
(43) Pub. Date: Feb. 26, 2026

(54) SEMICONDUCTOR DEVICE

(71) Applicant: SK hynix Inc., Gyeonggi-do (KR)

(72) Inventors: Wha Young KIM, Gyeonggi-do (KR); Dong Jin KO, Gyeonggi-do (KR); Se Hyun KIM, Gyeonggi-do (KR); Gyeong Cheol PARK, Gyeonggi-do (KR); Jun Hwe CHA, Gyeonggi-do (KR)

(21) Appl. No.: 19/299,354

(22) Filed: Aug. 14, 2025

(30) Foreign Application Priority Data
Aug. 26, 2024 (KR) 10-2024-0114381

(51) Int. Cl. G01R 31/28; H01L 21/66; H01L 23/522; H01L 23/528; H01L 23/532

(52) U.S. Cl. CPC G01R 31/2853; G01R 31/2884; H01L 22/32; H01L 23/5226; H01L 23/5283; H01L 23/5329

(57) ABSTRACT

A semiconductor device including a hydrogen test pattern for testing the influence of hydrogen on an insulation layer is disclosed. The semiconductor device includes a target insulation layer shared by a transistor pattern disposed in a first region and a test pattern disposed in a second region. The test pattern includes detection interconnect elements disposed within the target insulation layer, and outputs a test current corresponding to a test voltage provided through the detection interconnect elements.

### CROSS-REFERENCE TO RELATED APPLICATION

This patent application claims the priority and benefits of Korean patent application No. 10-2024-0114381, filed on Aug. 26, 2024, the disclosure of which is incorporated herein by reference in its entirety.

### TECHNICAL FIELD

The technology and embodiments of the present disclosure generally relate to a semiconductor device, and more particularly to a semiconductor device including a hydrogen test pattern for testing the influence of hydrogen on an insulation layer.

### BACKGROUND

The physical characteristics and electrical properties of insulation layers included in a semiconductor device may change due to the influence of either a process in a high-temperature environment or a hydrogen reduction reaction during a semiconductor manufacturing process.

In particular, a breakdown voltage of an insulation layer included in a semiconductor device may increase as dangling bonds of silicon included in the insulation layer and hydrogen introduced into the insulation layer are combined and a defect concentration in the insulation layer decreases.

Since the breakdown voltage varies depending on the amount of hydrogen inflow into the insulation layer, it is essential to confirm the amount of hydrogen inflow and the influence of such hydrogen inflow in order to predict the electrical properties of the insulation layer.

However, according to a conventional semiconductor device, there was no method for confirming the influence of hydrogen on the insulation layer. Therefore, a test pattern capable of confirming the influence of hydrogen on the insulation layer is required.

### SUMMARY

Various embodiments of the present disclosure relate to a semiconductor device that includes a test pattern capable of confirming the influence of hydrogen on an insulation layer included in the semiconductor device.

Various embodiments of the present disclosure relate to a semiconductor device that includes a test pattern for each insulation layer for individually confirming the influence of hydrogen on each insulation layer.

Various embodiments of the present disclosure relate to a semiconductor device including a test pattern that can be formed using a manufacturing process of the semiconductor device.

In accordance with some embodiments of the present disclosure, a semiconductor device may include a target insulation layer shared by a transistor pattern disposed in a first region and a test pattern disposed in a second region, wherein the test pattern includes detection interconnect elements disposed within the target insulation layer, and outputs a test current corresponding to a test voltage provided through the detection interconnect elements.

In some embodiments, at least a portion of the target insulation layer may be disposed between the detection interconnect elements.

In some embodiments, the test pattern may be electrically isolated from the transistor pattern.

In some embodiments, the target insulation layer may include, for example, silicon nitride.

In some embodiments, the detection interconnect elements may be respectively connected to the vertical contact elements, and a width between the detection interconnect elements may be narrower than a width between the vertical contact elements.

In some embodiments, the vertical contact elements may be respectively connected to interconnect portions, and the width between the detection interconnect elements may be narrower than the width between the interconnect portions.

In some embodiments, the target insulation layer may be passivated by hydrogen.

In some embodiments, the target insulation layer may prevent hydrogen from flowing into a lower region.

In some embodiments, the lower region disposed in the first region may include a channel region of the transistor pattern.

In some embodiments, the channel region may include an oxide semiconductor material.

In some embodiments, the detection interconnect elements may include a metal material.

In accordance with another embodiment of the present disclosure, a semiconductor device may include a first region in which a plurality of transistor patterns is disposed; a second region in which a plurality of test patterns is disposed; and a plurality of insulation layers disposed across the first region and the second region. Any one of the plurality of test patterns may include detection interconnect elements disposed in a target insulation layer among the plurality of insulation layers; and vertical contact elements disposed in another insulation layer contacting the target insulation layer, wherein a width between the detection interconnection elements is narrower than a width between the vertical contact elements.

In some embodiments, at least a portion of the target insulation layer may be disposed between the detection interconnect elements.

In some embodiments, any one of the plurality of test patterns may output a test current corresponding to a received test voltage.

In some embodiments, the plurality of test patterns may use different insulation layers among the plurality of insulation layers as target insulation layers.

In some embodiments, the detection interconnect elements and the vertical contact elements may include a conductive material.

In some embodiments, any of the plurality of test patterns may further include interconnect portions that are connected to the vertical contact elements and are disposed in an insulation layer different from the target insulation layer, wherein a width between the detection interconnect elements is narrower than a width between the interconnect portions.

In some embodiments, the interconnect portions included in one of the plurality of test patterns may be disposed on the same insulation layer as the detection interconnect elements included in another one of the plurality of test patterns.

It is to be understood that both the foregoing general description and the following detailed description of the present disclosure are illustrative and are intended to provide further description of the embodiments of the present disclosure as claimed.

### BRIEF DESCRIPTION OF THE DRAWINGS

The above and other features and beneficial aspects of the embodiments of the present disclosure will become readily apparent with reference to the following detailed description when considered in conjunction with the accompanying drawings.

FIG. 1 is a cross-sectional view illustrating a semiconductor device according to, some embodiments of the present disclosure.

FIG. 2 is a cross-sectional view illustrating an example of a semiconductor device according to another embodiment of the present disclosure.

FIG. 3 is a cross-sectional view illustrating an arrangement shape of detection interconnect elements associated with target insulation layers.

FIGS. 4 to 16 are cross-sectional views illustrating methods for manufacturing the semiconductor device according to some embodiments of the present disclosure.

FIGS. 17 to 23 are cross-sectional views illustrating methods for manufacturing the semiconductor device according to other embodiments of the present disclosure.

### DETAILED DESCRIPTION

According to the present disclosure various embodiments of a semiconductor device are disclosed which include a hydrogen test pattern. The hydrogen test pattern may test the influence of hydrogen on an insulation layer that may be used in configurations to substantially address one or more technical or engineering issues and to mitigate limitations or disadvantages encountered in some other semiconductor devices. Some embodiments of the present disclosure relate to a semiconductor device that includes a test pattern capable of confirming the influence of hydrogen on an insulation layer included in the semiconductor device. Some embodiments of the present disclosure relate to a semiconductor device that includes a test pattern for each insulation layer so that the influence of hydrogen on each insulation layer can be individually confirmed. Some embodiments of the present disclosure relate to a semiconductor device including a test pattern that can be formed using a manufacturing process of the semiconductor device. In recognition of the issues above, the semiconductor device based on some embodiments of the present disclosure may include a test pattern disposed in a target insulation layer, which is a target of confirmation of a breakdown voltage, from among a plurality of insulation layers included in the semiconductor device. The test pattern may have a metal-insulation layer-metal structure, and the target insulation layer may be disposed between interconnect portions including metal. As a result, a breakdown voltage, which is a voltage at which a test current greater than a threshold current (critical current) flows when the target insulation layer breaks down, may be detected.

Reference will now be made in detail to the embodiments of the present disclosure, examples of which are illustrated in the accompanying drawings. Wherever possible, the same reference numbers will be used throughout the drawings to refer to the same or like parts. While the embodiments of the present disclosure are susceptible to various modifications and alternative forms, specific embodiments thereof are shown by way of example in the drawings. However, the embodiments should not be construed as being limited to the specific embodiments set forth herein.

Hereinafter, various embodiments will be described with reference to the accompanying drawings. However, it should be understood that the embodiments of the present disclosure are not limited to specific embodiments, but include various modifications, equivalents and/or alternatives of the embodiments. The embodiments of the present disclosure may provide a variety of advantageous effects capable of being directly or indirectly recognized.

In the following description, a detailed description of related known configurations or functions incorporated herein will be omitted to avoid obscuring the subject matter.

The terminology used herein is for the purpose of describing particular embodiments only and is not intended to be limiting. As used herein, the singular forms are intended to include the plural forms as well, unless the context clearly indicates otherwise. It will be further understood that the terms “comprises”, “includes”, “including”, and/or “comprising,” when used in this specification, specify the presence of stated constituent elements, steps, operations, and/or components, but do not preclude the presence or addition of one or more other constituent elements, steps, operations, and/or components thereof. The term “and/or” may include a combination of a plurality of items or any one of a plurality of items.

Hereinafter, a semiconductor device and a method for manufacturing the same based on some embodiments of the present disclosure will be described in detail with reference to the attached drawings.

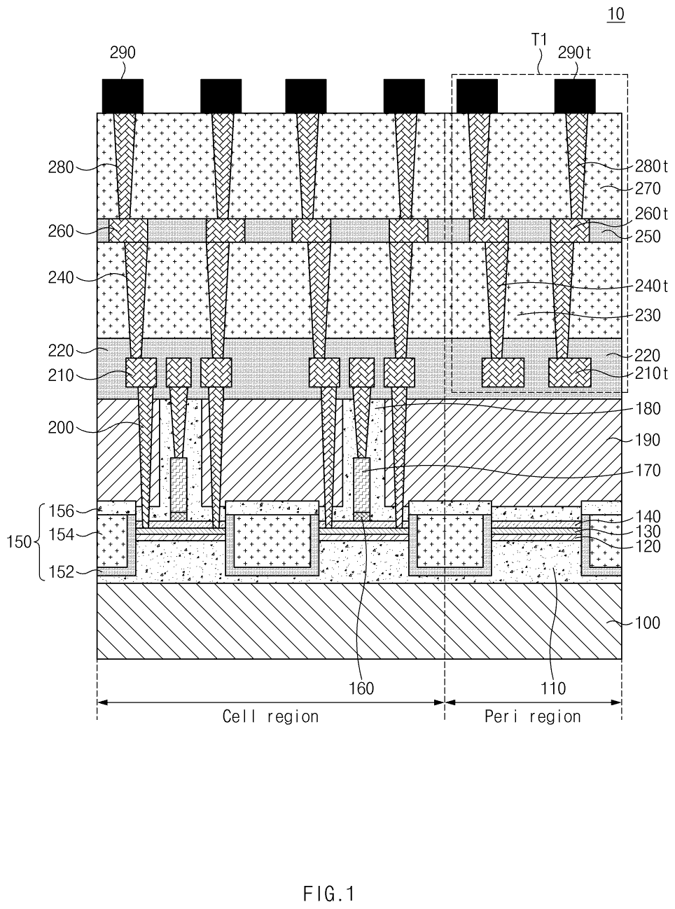

FIG. 1 is a cross-sectional view illustrating a semiconductor device 10 according to some embodiments of the present disclosure.

Referring to FIG. 1, the semiconductor device 10 may include a cell region and a peripheral region (also called a peri region). The cell region may be a region where transistor patterns are located, and the peripheral region may be a region where test patterns (T1) are located. The cell region and the peripheral region may be referred to as a first region and a second region, respectively.

As an example, the cell region may include transistor patterns, and the peripheral region may include test patterns (T1).

However, the test patterns (T1) may not only be placed in the peripheral region, and in some embodiments, the test patterns (T1) may also be arranged in the cell region as may be needed.

The semiconductor device 10 may include a substrate layer 100 including a material suitable for semiconductor processing. For example, the substrate layer 100 may be a semiconductor substrate including silicon, monocrystalline silicon, polysilicon, amorphous silicon, silicon germanium, monocrystalline silicon germanium, polycrystalline silicon germanium, carbon-doped silicon, or a combination thereof. The substrate may be a single layer or a multilayer.

In some embodiments, the substrate 100 may include other semiconductor materials such as germanium, a group III/V semiconductor substrate, for example, a compound semiconductor substrate such as GaAs, and a silicon-on-insulator (SOI) substrate.

An upper insulation layer 110 of the substrate 100 (hereinafter referred to as a substrate upper insulation layer 110) may be disposed on the substrate layer 100. The substrate upper insulation layer 110 may be, for example, an insulation layer including silicon nitride, silicon oxide, and the like.

A channel lower insulation layer 120, a channel region 130, and a channel upper insulation layer 140 may be arranged on the upper surface (also referred to as a top surface) of the substrate upper insulation layer 110. For example, the channel lower insulation layer 120 may include silicon oxide.

The channel region 130 may also be referred to as an active region. The channel region 130 may include a source/drain region of a transistor pattern. In some embodiments, the channel region 130 may include silicon doped with impurities or an oxide semiconductor material.

For example, the channel region 130 may include doped polysilicon, undoped polysilicon, amorphous silicon, amorphous IGZO (indium gallium zinc oxide), indium zinc oxide (IZO), indium tin oxide (ITO), indium oxide (InO₃), and the like.

The channel upper insulation layer 140 may be a region that electrically isolates the channel region 130 from the first gate layer 160 and the second gate layer 170. For example, the channel upper insulation layer 140 may include silicon oxide.

The channel lower insulation layer 120, the channel region 130, and the channel upper insulation layer 140 may be referred to collectively as channel structures. Adjacent channel structures may be isolated from each other by a spacer 150.

The spacer 150 may include a plurality of layers, and the channel structures isolated from each other by the spacer 150 may operate as channel regions of different transistors.

The spacers 150 may be arranged at predetermined intervals within the substrate upper insulation layer 110. Each of the spacers 150 may be formed in a trench shape within the substrate upper insulation layer 110.

The spacer 150 may include a first spacer insulation layer 152, a second spacer insulation layer 154, and a third spacer insulation layer 156.

The first spacer insulation layer 152 may include, for example, silicon nitride, and may be formed conformally along a bottom surface and sidewalls of the trench in the substrate upper insulation layer 110.

The second spacer insulation layer 154 may include, for example, silicon oxide, and may be formed on the first spacer insulation layer 152 and may be formed to fill the trench formed in the substrate upper insulation layer 110.

A third spacer insulation layer 156 may be formed on the second spacer insulation layer 154, and may be a layer formed together with at least a portion of the gate insulation layer 180. The third spacer insulation layer 156 may include, for example, silicon nitride.

The first gate layer 160 and the second gate layer 170 may be referred to as gates of the transistor pattern. According to some embodiments, the first and second gate layers 160 and 170 may operate as word lines of the transistor pattern.

Each of the first and second gate layers 160 and 170 may be a layer including a conductive material. For example, the first gate layer 160 may include titanium nitride (TiN), and the second gate layer 170 may include tungsten (W).

According to an embodiment, a word-line control voltage may be provided to the first gate layer 160 and the second gate layer 170. The word-line control voltage may be provided to the first gate layer 160 and the second gate layer 170 through the first interconnect portion 210 and the first vertical contact element 200.

The gate insulation layer 180 may be arranged along the side surfaces of the first gate layer 160, the second gate layer 170, and the first vertical contact element 200, and may electrically isolate the first gate layer 160, the second gate layer 170, and the first vertical contact element 200 from other adjacent vertical contact elements or other adjacent gates.

The gate insulation layer 180 may include, for example, silicon nitride, and may have a shape extending from the side surfaces of the first gate layer 160, the second gate layer 170, and the first vertical contact element 200 to an upper portion of the channel upper insulation layer 140.

A first interlayer insulation layer 190 may include silicon oxide. At least a portion of the first interlayer insulation layer 190 may be etched, and a first vertical contact element 200 may be formed in the etched portion. Some of the first vertical contact elements 200 may be connected to a channel region 130.

The first vertical contact element 200 may include a conductive material. For example, the first vertical contact element 200 may include a metal material.

A second interlayer insulation layer 220 may be formed on the first interlayer insulation layer 190.

For example, the second interlayer insulation layer 220 may include, for example, silicon nitride. The second interlayer insulation layer 220 may electrically isolate adjacent first interconnect portions 210 from each other. Additionally, at least a portion of the second interlayer insulation layer 220 may be disposed between the first interconnect portions 210.

For example, the second interlayer insulation layer 220 may include, for example, silicon nitride, so that electrical properties may change due to hydrogen passivation.

For example, during the semiconductor manufacturing process, dangling bonds contained in the silicon nitride may be combined with incoming hydrogen, and as the concentration of the dangling bonds decreases, a breakdown voltage of the silicon nitride layer may increase.

The breakdown voltage may refer to a voltage at which a current exceeding a threshold current flows when a high voltage exceeding the threshold voltage is applied to an insulation material.

That is, a defect concentration of the silicon nitride layer may decrease due to incoming hydrogen during the semiconductor manufacturing process, so that changes in the electrical properties of the silicon nitride layer may occur. Therefore, it may be necessary to verify the changes in the electrical properties of the interlayer insulation layer due to hydrogen.

Among the plurality of interlayer insulation layers (190, 220, 230, 250, 270) included in the semiconductor device 10, the interlayer insulation layers (e.g., 220, 250) which may include, for example, silicon nitride may have significant changes in the physical properties due to hydrogen passivation. In addition, the interlayer insulation layers (220, 250) which may include, for example, silicon nitride may be combined with the incoming hydrogen, so that the interlayer insulation layers (220, 250) may prevent hydrogen from entering lower portions of the interlayer insulation layers (220, 250).

The interlayer insulation layers (220, 250) including silicon nitride may prevent hydrogen passivation from affecting lower layers. The lower layers to which no hydrogen passivation is applied may include, for example, a channel region 130, etc.

A plurality of first interconnect portions 210 may be formed within the second interlayer insulation layer 220, each including a conductive material. For example, each of the first interconnect portions 210 may include a metal material.

A third interlayer insulation layer 230 may be formed on the second interlayer insulation layer 220. For example, the third interlayer insulation layer 230 may further include silicon oxide.

A plurality of second vertical contact elements 240 may be formed across the range from the third interlayer insulation layer 230 to the second interlayer insulation layer 220. The second vertical contact elements 240 may be formed by etching the range from the third interlayer insulation layer 230 to the second interlayer insulation layer 220 and disposing a conductive material in the etched region. For example, the second vertical contact portions 240 may include a metal material.

The second vertical contact elements 240 may each electrically connect a corresponding first interconnect portion 210 to a corresponding second interconnect portion 260.

The second interconnect portion 260 may be formed on the second vertical contact element 240. The second interconnect portion 260 may be formed inside the fourth interlayer insulation layer 250. The fourth interlayer insulation layer 250 may include, for example, silicon nitride.

A fifth interlayer insulation layer 270 may be disposed on the fourth interlayer insulation layer 250. The fifth interlayer insulation layer 270 may include, for example, silicon oxide. At least a portion of the fifth interlayer insulation layer 270 may be etched, and a plurality of third vertical contact elements 280 may be formed in the etched region. The third vertical contact elements 280 may include a conductive material. For example, the third vertical contact elements 280 may include a metal material.

A power-supply circuit 290 may be formed on the third vertical contact element 280. The power-supply circuit 290 may be a region that is connected to an external device for receiving external power from the external device.

In the embodiment of FIG. 1, a test pattern (T1) may be disposed in a peripheral region. The test pattern (T1) may be formed across the second interlayer insulation layer 220, the third interlayer insulation layer 230, the fourth interlayer insulation layer 250, and the fifth interlayer insulation layer 270.

The test pattern (T1) may include a first test interconnect portion 210t, a second test vertical contact element 240t, a second test interconnect portion 260t, a third test vertical contact element 280t, and a test power-supply circuit 290t.

Among the test interconnect portions (210t, 260t) included in the test pattern (T1) illustrated in FIG. 1, the first test interconnect portion 210t may hereinafter be referred to as a detection interconnect element.

The detection interconnect element 210t may be an interconnect portion disposed within a target insulation layer (e.g., 220) that is a detection target for the breakdown voltage, among the plurality of interlayer insulation layers (220, 230, 250, 270) included in the test pattern (T1).

Hence, as an example, the target insulation layer 220 (also referred to as the second interlayer insulation layer) and one pair of detection interconnect elements 210t may form a metal-insulator-metal (MIM) capacitor structure. One pair of detection interconnect elements 210t may be one pair of electrodes of the MIM capacitor, and a target insulation layer 220 may be a dielectric of the MIM capacitor.

As the target insulation layer 220 and one pair of detection interconnect elements 210t form the MIM capacitor, an arbitrary test voltage may be provided to the detection interconnect element 210t.

The test pattern (T1) may output a test current corresponding to the provided test voltage, and an external device providing the test voltage may detect a breakdown voltage of the target insulation layer 220 included in the test pattern (T1) based on the output test current.

The breakdown voltage may be a voltage at which a target insulation layer 220 included in the MIM capacitor breaks down so that a test current greater than a threshold current flows in the MIM capacitor. Thus, it is possible to check whether the target insulation layer 220 is destroyed based on the test current of the MIM capacitor corresponding to the test voltage.

The breakdown voltage may be proportional to a thickness of the target insulation layer 220 disposed between two detection interconnect elements 210t. In addition, when the target insulation layers 220 have the same thickness and the same composition material, the lower the concentration of defects (hereinafter referred to as defect concentration) included in the target insulation layer 220, the higher the breakdown voltage. When the target insulation layers 220 have the same thickness and are composed of the same material, a lower concentration of defects (hereinafter referred to as defect concentration) in the target insulation layer 220 results in a higher breakdown voltage.

Therefore, the defect concentration of the target insulation layer 220 may be confirmed based on the breakdown voltage of the target insulation layer 220.

The detection interconnect element 210t may be configured such that the width between adjacent interconnect portions from among the plurality of test interconnection portions (210t, 260t) included in the test pattern (T1) is the narrowest width.

Since the width between the detection interconnect elements 210t disposed within the target insulation layer 220 (which is a detection target of the breakdown voltage) is determined to be the narrowest width, the breakdown voltage of the target insulation layer 220 can be easily detected.

When the width between the interconnect portions (e.g., 260t) disposed within the insulation layer that is not the detection target is the narrowest, the breakdown voltage of the other insulation layer 250 other than the target insulation layer 220 can be detected.

According to another embodiment, the target insulation layer can be selected by adjusting the distance between the test interconnect portions (210t, 260t) included in the test pattern (T1). For example, when the fourth interlayer insulation layer 250 is used as the target insulation layer, the breakdown voltage of the fourth interlayer insulation layer 250 can be detected because the width between the two second test interconnect portions (i.e., one pair of second test interconnect portions) 260t is set to the narrowest width.

The test pattern (T1) may be electrically isolated from the transistor patterns disposed in a cell region. In addition, the test patterns (T1) disposed in the peripheral region may also be electrically isolated from each other.

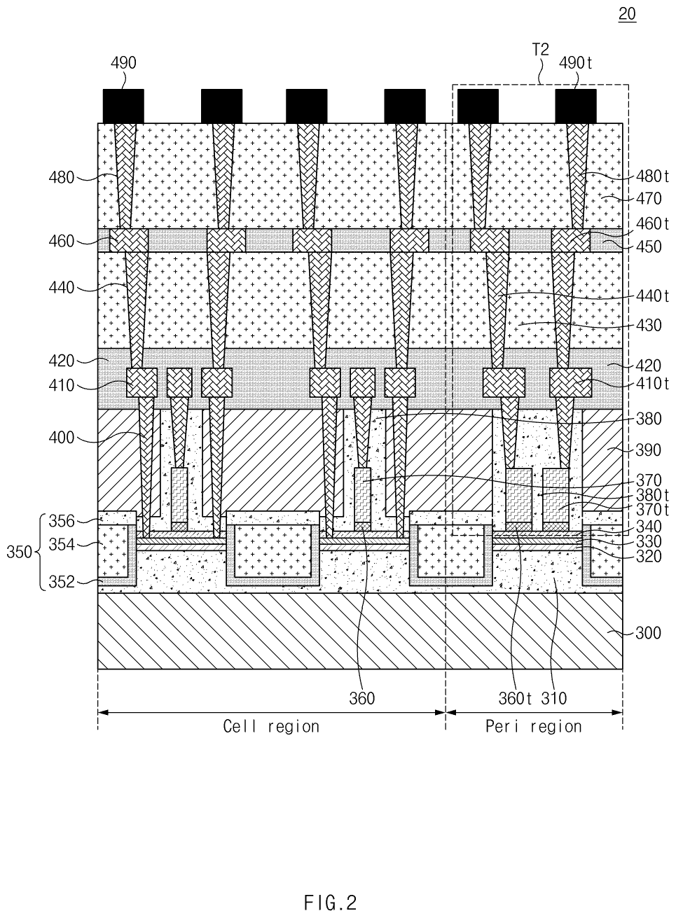

FIG. 2 is a cross-sectional view illustrating a semiconductor device 20 according to another embodiment of the present disclosure.

The semiconductor device 20 according to the embodiment of FIG. 2 may be substantially the same as the semiconductor device 10 of FIG. 1 except for the test pattern (T2). Therefore, redundant descriptions will herein be omitted for brevity.

The semiconductor device 20 according to the embodiment of FIG. 2 may include a cell region and a peripheral region.

The cell region of the semiconductor device 20 may be substantially the same as the cell region of the semiconductor device 10 illustrated in FIG. 1.

The semiconductor device 20 may include a substrate layer 300 including a material suitable for semiconductor processing. A substrate upper insulation layer 310 may be disposed on the substrate layer 300 and may include, for example, silicon nitride.

A channel lower insulation layer 320, a channel region 330, and a channel upper insulation layer 340 may be disposed on the substrate upper insulation layer 310.

A plurality of spacers 350 may define a plurality of channel regions 330. Adjacent channel regions 330 may be isolated from each other by a corresponding spacer 350. Thus, the isolated channel regions 330 can operate as channel regions of different transistors. Each of the spacers 350 may include a first spacer insulation layer 352, a second spacer insulation layer 354, and a third spacer insulation layer 356.

The first spacer insulation layer 352 may include, for example, silicon nitride, and may overlap the bottom surface and side surfaces of a trench formed in the substrate upper insulation layer 310.

The second spacer insulation layer 354 may include, for example, silicon oxide, and may be formed not only on the first spacer insulation layer 352 but also in the trench.

The third spacer insulation layer 356 may include, for example, silicon nitride as a layer formed together with at least a portion of the gate insulation layer 380.

The first gate layer 360 and the second gate layer 370 are layers including a conductive material, so that each of the first gate layer 360 and the second gate layer 370 may operate as a word line of a transistor pattern. The second gate layer 370 may be connected to the first vertical contact element 400, and may receive a word-line control voltage from the first vertical contact element 400.

The gate insulation layer 380 may be arranged along the side surfaces of the first gate layer 360, the second gate layer 370, and the first vertical contact element 400.

The first interlayer insulation layer 390 may include silicon oxide. At least a portion of the first interlayer insulation layer 390 may be etched, and the first vertical contact element 400 may be formed in the etched region. Some of the first vertical contact elements 400 may be connected to the channel region 330. The first vertical contact elements 400 may include a metal material.

A second interlayer insulation layer 420 may be formed on the first interlayer insulation layer 390, and a first interconnect portion 410 may be disposed in the second interlayer insulation layer 420. The first interconnect portions 410 may be electrically isolated from each other by the second interlayer insulation layer 420. The first interconnect portions 410 may include a conductive material.

A third interlayer insulation layer 430 may be formed on the second interlayer insulation layer 420. The third interlayer insulation layer 430 may further include silicon oxide.

A second vertical contact element 440 may be formed by etching at least a portion of the third interlayer insulation layer 430 and the second interlayer insulation layer 420, and then arranging a conductive material in the etched region.

The second vertical contact element 440 may electrically connect the first interconnect portion 410 to the second interconnect portion 460.

A fourth interlayer insulation layer 450 may be formed on the third interlayer insulation layer 430. The fourth interlayer insulation layer 450 may include, for example, silicon nitride. A second interconnect portion 460 may be formed within the fourth interlayer insulation layer 450. The second interconnect portion 460 may include a metal material.

A fifth interlayer insulation layer 470 may be formed on the fourth interlayer insulation layer 450. The fifth interlayer insulation layer 470 may include silicon oxide. At least a portion of the fifth interlayer insulation layer 470 may be etched, and a third vertical contact element 480 may be formed in the etched region. The third vertical contact element 480 may include a conductive material, and may electrically connect the second interconnect portion 460 to the power-supply circuit 490.

The semiconductor device 20 according to the embodiment of FIG. 2 may include a test pattern (T2) in the peripheral region.

However, the positions of the test patterns (T2) according to the present disclosure are not limited to the peripheral region, and the test patterns (T2) may also be arranged in the cell region according to the embodiments.

The test pattern (T2) may output a test current corresponding to the provided test voltage, and an external device providing the test voltage may detect the breakdown voltage of the gate insulation layer 380 based on the output test current.

The test pattern (T2) may include a first test gate layer 360t and a second test gate layer 370t. The first test gate layer 360t and the second test gate layer 370t may be referred to as test gates.

A test gate insulation layer 380t including the same material as the gate insulation layer 380 may be disposed between two test gates indicating one pair of test gates.

The pair of test gates and the test gate insulation layer 380t may form a MIM capacitor.

An arbitrary test voltage may be provided to the pair of test gates, and the test pattern (T2) may output a test current corresponding to the provided test voltage.

An external device providing a test voltage may output a test voltage having a test current greater than a threshold value as a breakdown voltage of the test gate insulation layer 380t. The breakdown voltage for the test gate insulation layer 380t may be substantially the same as the breakdown voltage of the gate insulation layer 380. Since the breakdown voltage of the gate insulation layer 380 is detected through the test pattern (T2), a change in electrical properties of the gate insulation layer 380 due to hydrogen passivation can be confirmed.

By confirming the change in electrical properties of the gate insulation layer 380, fluctuation in threshold voltage of the transistor pattern or the reliability of the gate insulation layer 380, etc. can be easily predicted.

A second test gate layer 370t may be connected to a first test vertical contact element 400t, and the first test vertical contact element 400t may be connected to a second test vertical contact element 440t through a first test interconnect portion 410t.

The first test interconnect portion 410t may be disposed within the second interlayer insulation layer 420.

The second test vertical contact element 440t may be formed within the third interlayer insulation layer 430, and may be connected to a third test vertical contact element 480t by a second test interconnect portion 460t. The third test vertical contact element 480t may be electrically connected to a test power supply section 490t.

The second test interconnect portion 460t may be disposed within the fourth interlayer insulation layer 450, and the third test vertical contact element 480t may be disposed within the fifth interlayer insulation layer 470.

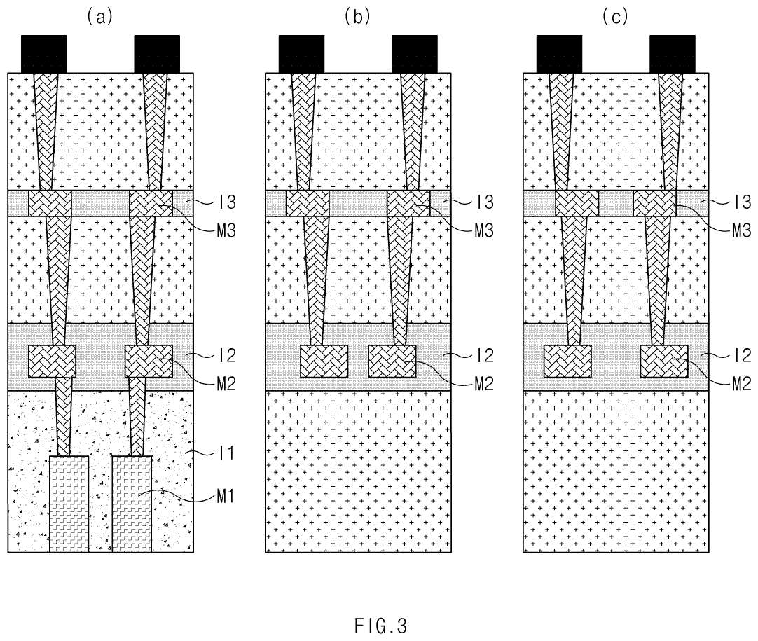

FIG. 3 is a cross-sectional view illustrating an arrangement shape of detection interconnect elements depending on target insulation layers.

(a), (b), and (c) of FIG. 3 illustrate test patterns that respectively use different insulation layers (I1, I2, I3) as target insulation layers.

Referring to (a) of FIG. 3, the width between the first interconnect portions (M1) disposed within the first interlayer insulation layer (I1) may be narrower than the width between the second interconnect portions (M2) or the width between the third interconnect portions (M3). Accordingly, the first interlayer insulation layer (I1) may operate as a target insulation layer, and the first interconnect portions (M1) having the narrowest width may operate as the detection interconnect elements.

The first interconnect portion (M1) of FIG. 3 may correspond to the first test gate layer 360t and the second test gate layer 370t of FIG. 2.

Referring to (b) and (c) of FIG. 3, the width between the second interconnect portions (M2) disposed within the second interlayer insulation layer (I2) of FIG. 3(b) may be narrower than the width between the third interconnect portions (M3).

On the other hand, as shown in (c) of FIG. 3, the width between the third interconnect portions (M3) disposed within the third interlayer insulation layer (I3) may be narrower than the width between the second interconnect portions (M2) disposed within the second interlayer insulation layer (I2).

In (b) of FIG. 3, the second interlayer insulation layer (I2) may be used as the target insulation layer. In (c) of FIG. 3, the third interlayer insulation layer (I3) may be used as the target insulation layer.

In some embodiments, a single semiconductor device may include a plurality of test patterns corresponding to (a), (b), and (c) of FIG. 3. The plurality of test patterns included in the semiconductor device may be elements for detecting breakdown voltages of different target insulation layers, respectively.

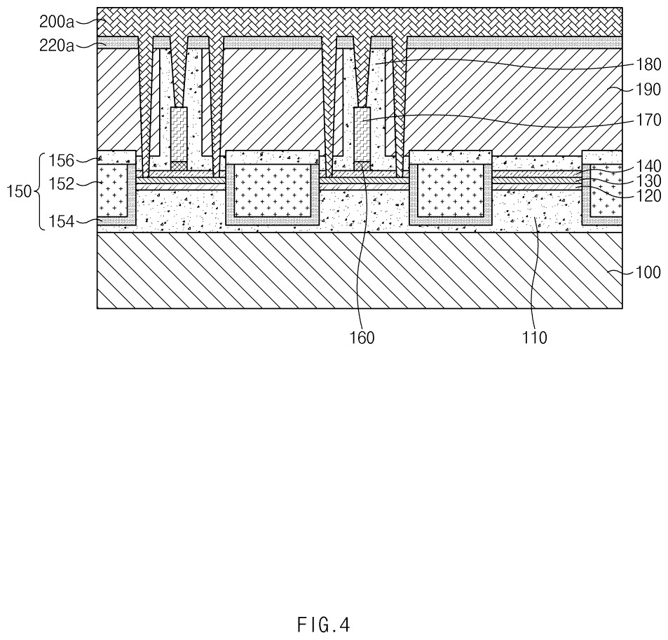

FIGS. 4 to 16 are cross-sectional views illustrating methods for manufacturing the semiconductor device according to some embodiments of the present disclosure.

Referring to FIG. 4, a first pre-vertical contact element 200a may be formed to penetrate at least a portion of the first interlayer insulation layer 190 and the lower portion 220a of the second interlayer insulation layer.

At least a portion of the first pre-vertical contact element 200a may be formed to overlap a lower portion 220a of the second interlayer insulation layer.

A first pre-vertical contact element 200a may include a conductive material, such as for example, a metal or a metal nitride such as tungsten or titanium nitride.

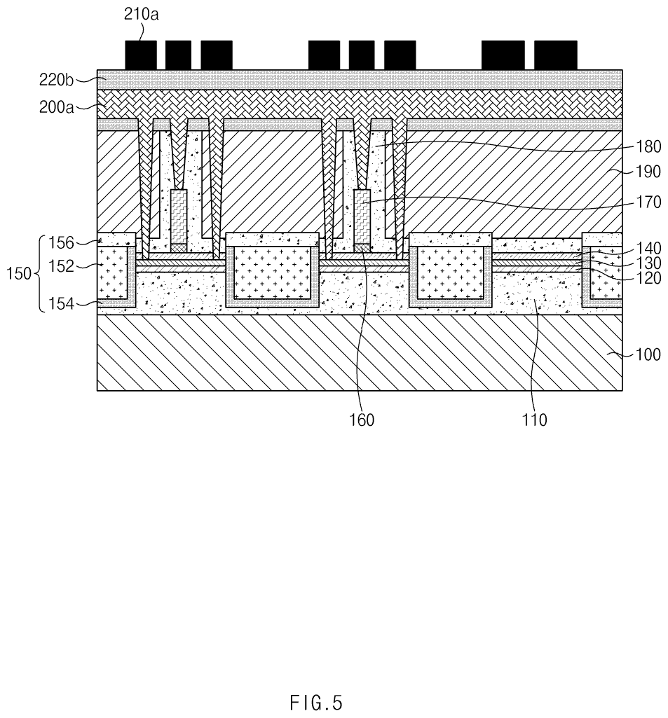

Referring to FIG. 5, an upper portion 220b of a second interlayer insulation layer may be formed on the first pre-vertical contact element 200a, and a first interconnect portion mask 210a may be formed on an upper portion 220b (also referred to as upper surface, or top surface) of the second interlayer insulation layer.

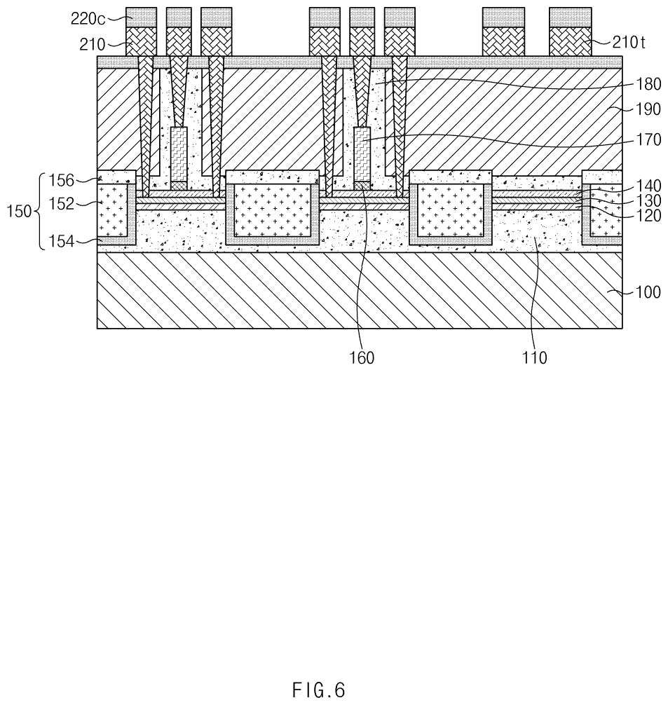

Referring to FIG. 6, at least a portion of the first pre-vertical contact element 200a and at least a portion of the upper portion 220b of the second interlayer insulation layer may be etched according to the shape of the first interconnect portion mask 210a of FIG. 5. As a portion of the first pre-vertical contact element 200a is selectively etched, a first interconnect portion 210 and a first test interconnect portion 210t may be formed.

In addition, the upper portion 220b of the second interlayer insulation layer that remains unused after being etched may hereinafter be referred to as a residual insulation layer 220c.

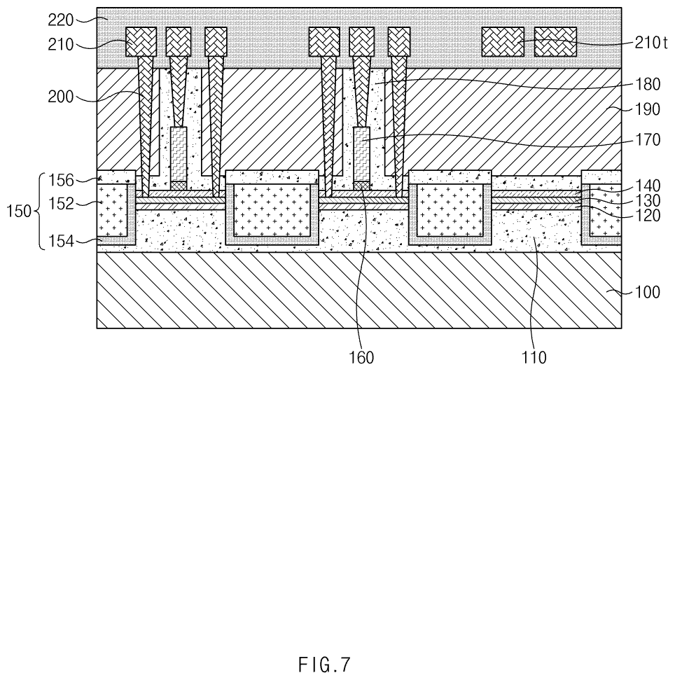

Referring to FIG. 7, a first interconnect portion 210 and a first test interconnect portion 210t may be formed within a second interlayer insulation layer 220. After the upper portion 220b of the second interlayer insulation layer is etched by a first interconnect portion mask 210a, a second interlayer insulation layer 220 may be formed by depositing silicon nitride. The adjacent first interconnect portions 210 or the first test interconnect portions 210t may be electrically isolated from each other by the second interlayer insulation layer 220.

In addition, at least a portion of the pair of first test interconnect portions 210t and at least a portion of the second interlayer insulation layer 220 may form a MIM capacitor.

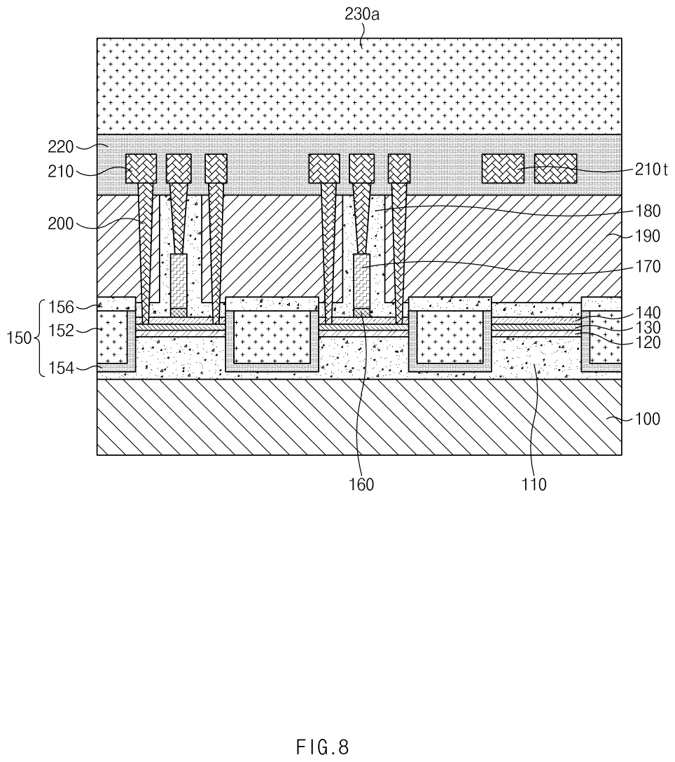

Referring to FIG. 8, a third pre-interlayer insulation layer 230a may be formed on the second interlayer insulation layer 220. The third pre-interlayer insulation layer 230a may include silicon oxide.

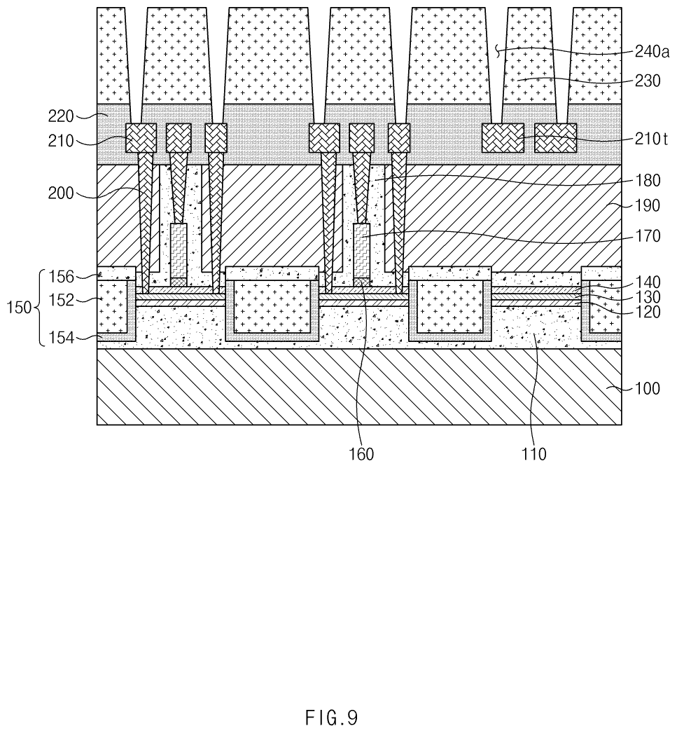

Referring to FIG. 9, at least a portion of the third pre-interlayer insulation layer 230a of FIG. 8 may be etched, and second vertical contact trenches 240a may be formed.

The second vertical contact trenches 240a may be formed by etching the third pre-interlayer insulation layer 230a and the second interlayer insulation layer 220, so that at least a portion of the first interconnect portion 210 may be formed to be opened.

A third interlayer insulation layer 230 may be disposed between the second vertical contact trenches 240a.

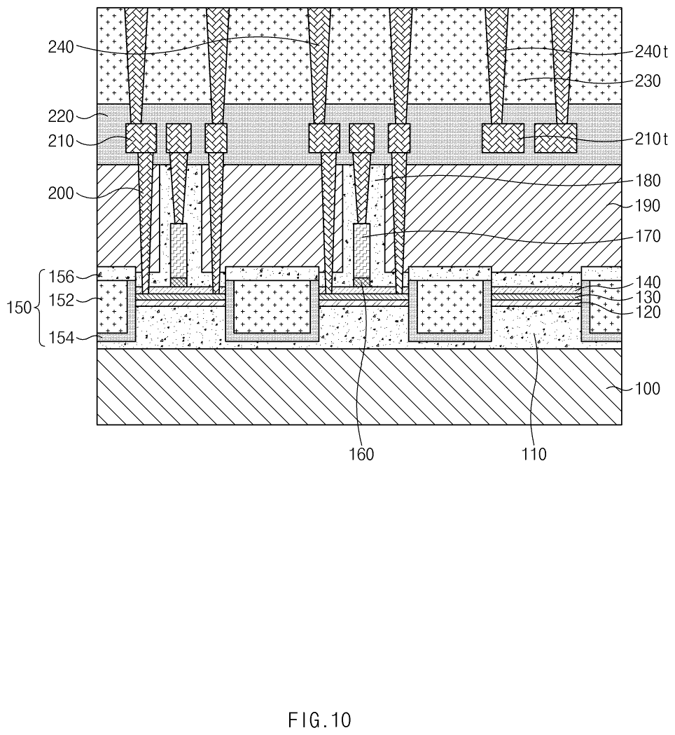

Referring to FIG. 10, a second vertical contact element 240 and a second test vertical contact element 240t may be formed in the second vertical contact element trench 240a. The second vertical contact element 240 may include a conductive material such as a metal or a metal nitride.

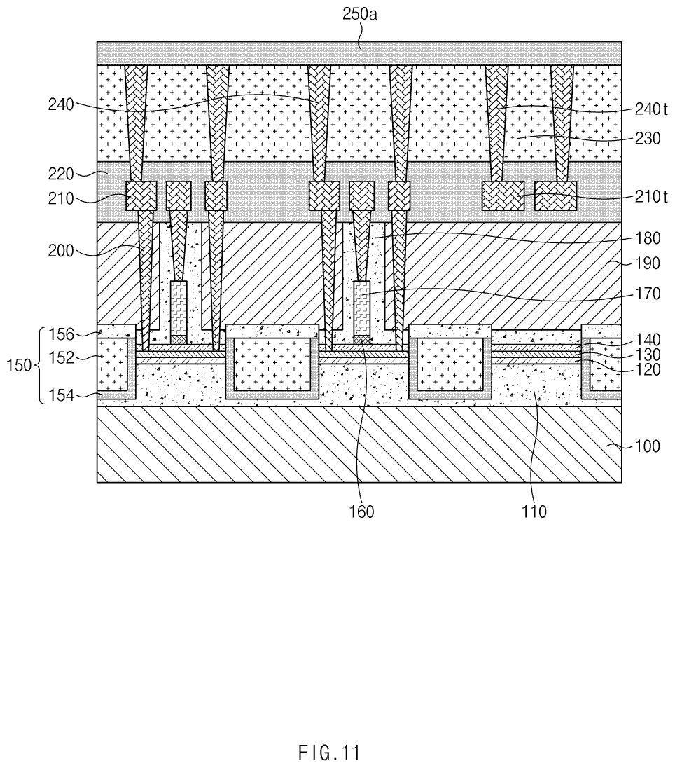

Referring to FIG. 11, a fourth pre-interlayer insulation layer 250a may be formed on the third interlayer insulation layer 230. The fourth pre-interlayer insulation layer 250a may include, for example, silicon nitride.

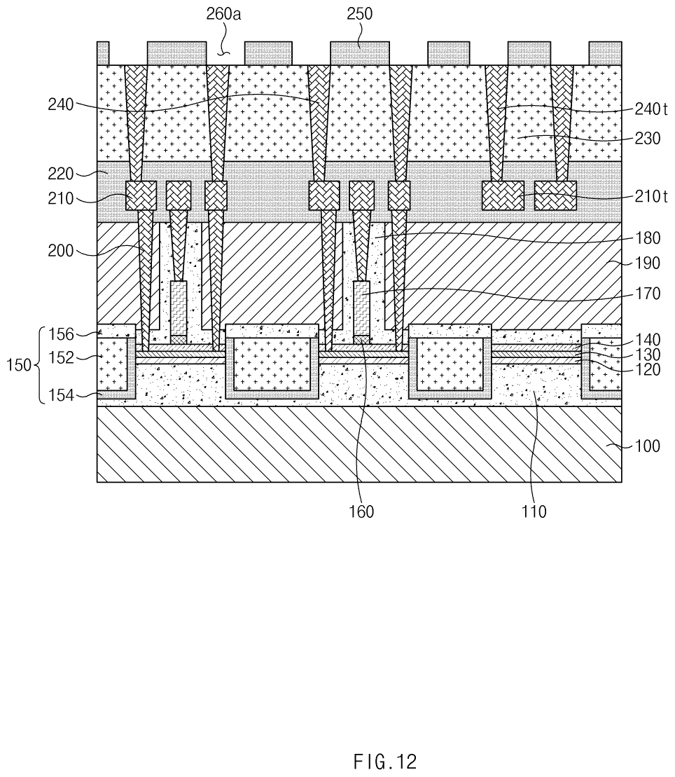

Referring to FIG. 12, at least a portion of the fourth pre-interlayer insulation layer 250a may be etched to form second interconnect trenches 260a, and a fourth interlayer insulation layer 250 may be formed.

Each of the second interconnect trenches 260a may be formed so that at least a portion of the second vertical contact element 240 or the second test vertical contact element 240t is opened.

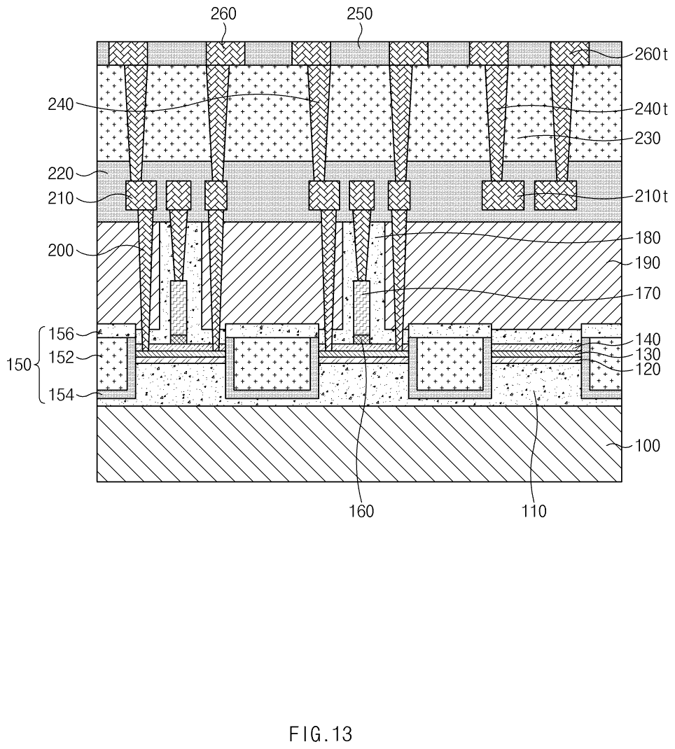

Referring to FIG. 13, the second interconnect portions 260 and the second test interconnect portions 260t may be formed in the second interconnect portion trenches 260a. The second interconnect portions 260 and the second test interconnect portions 260t may include a conductive material such as, for example, a metal or a metal nitride.

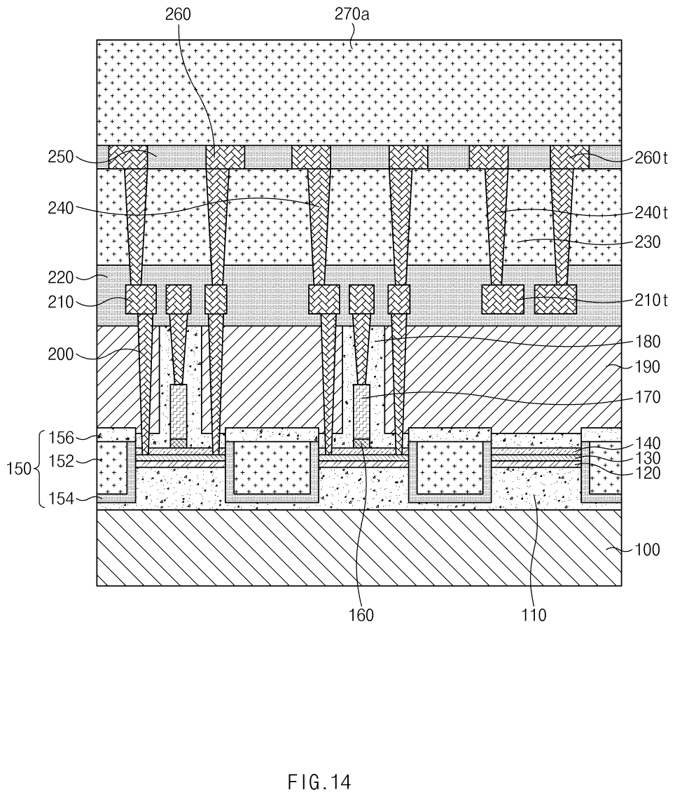

Referring to FIG. 14, a fifth pre-interlayer insulation layer 270a may be formed on the fourth interlayer insulation layer 250 and the second interconnect portions 260. The fifth pre-interlayer insulation layer 270a may include, for example, silicon oxide.

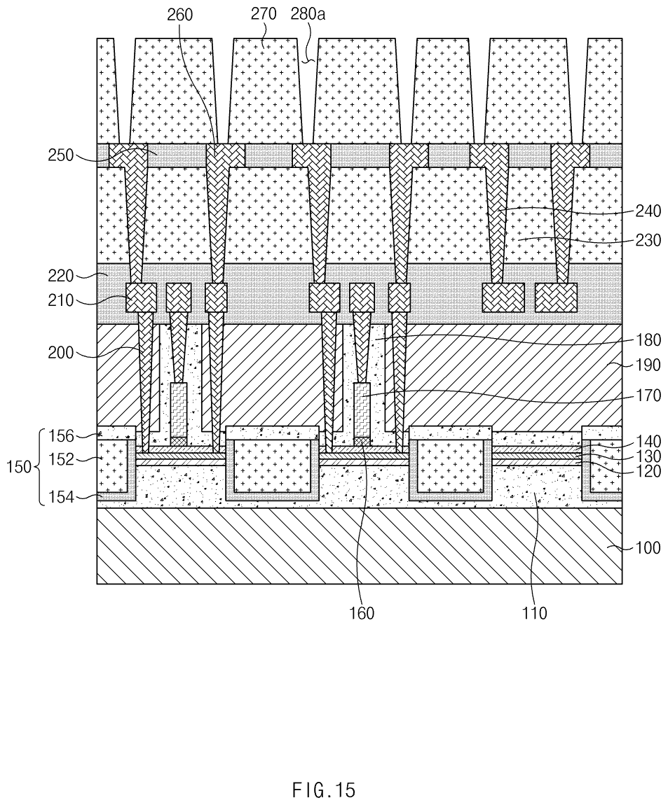

Referring to FIG. 15, at least a portion of the fifth pre-interlayer insulation layer 270a of FIG. 14 may be etched, and third vertical contact trenches 280a may be formed. Each of the third vertical contact trenches 280a may be formed to open at least a portion of a corresponding one of the second interconnect portions 260 or at least a portion of a corresponding one of the second test interconnect portions 260t.

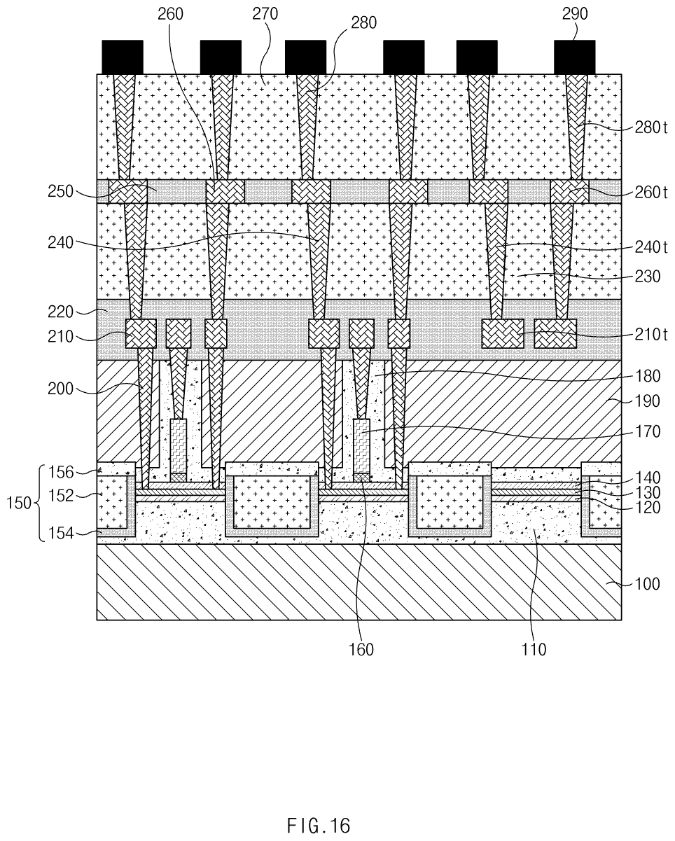

Referring to FIG. 16, a plurality of third vertical contact elements 280 and third test vertical contact elements 280t may be formed in the third vertical contact element trenches 280a, and a power-supply circuit 290 may be formed and may be connected to the third vertical contact elements 280 and the third test vertical contact elements 280t.

A fifth interlayer insulation layer 270 may be disposed between the third vertical contact elements 280 and the third test vertical contact elements 280t.

The third vertical contact elements 280 and the third test vertical contact elements 280t may include metal or metal nitride, and may receive external power through the power-supply circuit 290.

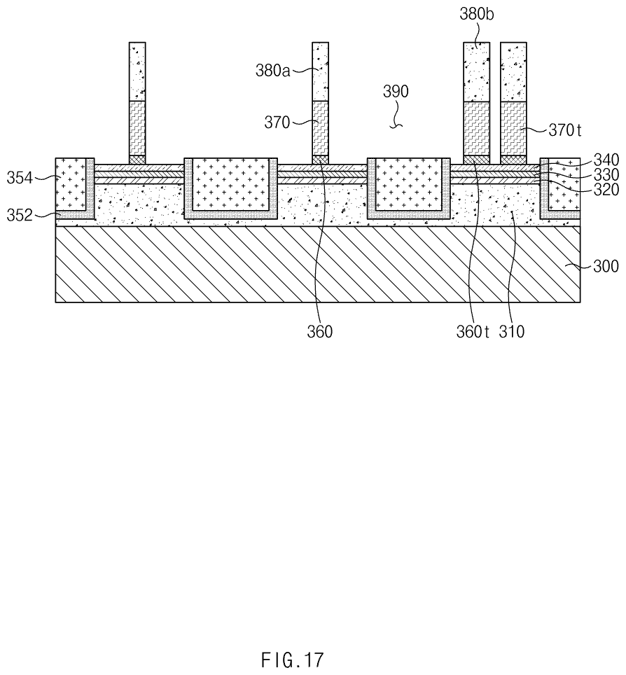

FIGS. 17 to 23 are cross-sectional views illustrating methods for manufacturing the semiconductor device according to another embodiment of the present disclosure.

Referring to FIG. 17, a first gate layer 360 may be formed on a channel upper insulation layer 340 disposed in the cell region, and a second gate layer 370 may be formed on the first gate layer 360. In addition, a first test gate layer 360t may be formed on the channel upper insulation layer 340 disposed in the peripheral region, and a second test gate layer 370t may be formed on the first test gate layer 360t.

The first test gate layer 360t and the second test gate layer 370t formed in the peripheral region may be formed by stacking the same material layers as the first gate layer 360 and the second gate layer 370 and then etching the remaining regions.

In some embodiments, the first test gate layer 360t and the second test gate layer 370t may include a conductive material. For example, the first test gate layer 360t may include titanium nitride, and the second test gate layer 370t may include tungsten.

A pre-gate insulation layer 380a may be formed on the second gate layer 370, and a pre-test gate insulation layer 380b may be formed on the second test gate layer 370t.

The pre-gate insulation layer 380a and the pre-test gate insulation layer 380b may operate as hard mask layers, and may represent layers for etching the first test gate layer 360t and the second test gate layer 370t. The pre-gate insulation layer 380a and the pre-test gate insulation layer 380b may include, for example, silicon nitride.

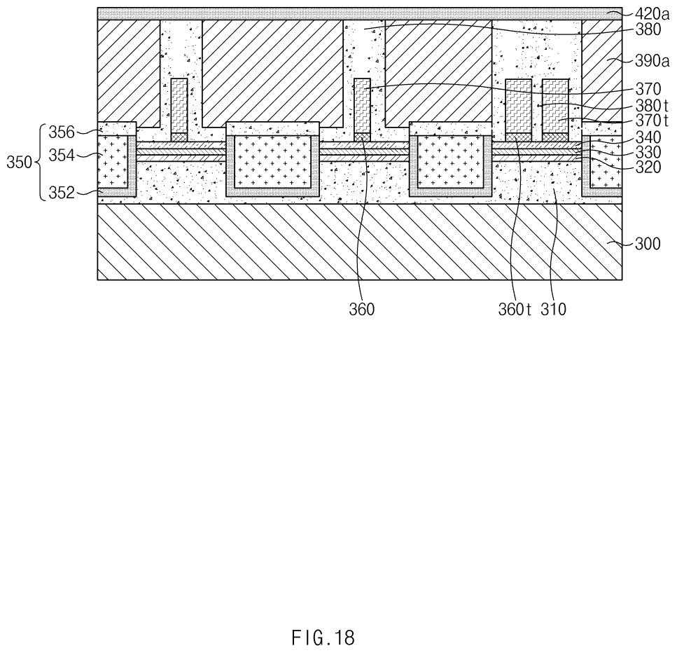

Referring to FIG. 18, a gate insulation layer 380 may be formed to contact the sidewalls of the first gate layer 360 and the second gate layer 370, and may include the same material as the pre-gate insulation layer 380a. In addition, a test gate insulation layer 380t may be formed to contact the sidewalls of the first test gate layer 360t and the second test gate layer 370t, and may include the same material as the pre-test gate insulation layer 380b.

The gate insulation layer 380 and the test gate insulation layer 380t may include, for example, silicon nitride. The gate insulation layer 380 may electrically isolate the first gate layer 360 and the second gate layer 370 from adjacent elements. In addition, the test gate insulation layer 380t may electrically isolate the first test gate layer 360t and the second test gate layer 370t from adjacent elements.

In addition, the third spacer insulation layer 356 may be formed together with at least a portion of the gate insulation layer 380 and the test gate insulation layer 380t.

For example, the third spacer insulation layer 356, the gate insulation layer 380, and the test gate insulation layer 380t may be formed through deposition.

A first pre-interlayer insulation layer 390a, including, for example, silicon oxide may be formed on the third spacer insulation layer 356, the gate insulation layer 380, and the test gate insulation layer 380t.

The first pre-interlayer insulation layer 390a may be formed to have the same height as the gate insulation layer 380 and the test gate insulation layer 380t from one surface of the substrate 300. A lower portion 420a of the second interlayer insulation layer may be formed on the first pre-interlayer insulation layer 390a. The lower portion 420a of the second interlayer insulation layer may include, for example, silicon nitride.

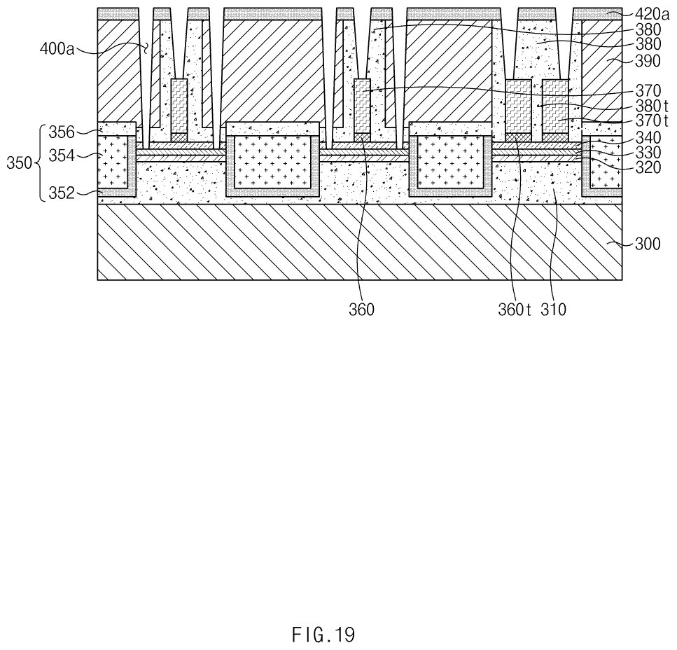

Referring to FIG. 19, at least a portion of the first pre-interlayer insulation layer 390a and at least a portion of the lower portion 420a of the second interlayer insulation layer may be etched, and a plurality of first pre-vertical contact trenches 400a may be formed across the first pre-interlayer insulation layer 390a and the lower portion 420a of the second interlayer insulation layer.

Among the plurality of first pre-vertical contact trenches 400a, at least some of the trenches may open at least a portion of the channel region 330. Additionally, some of the remaining first pre-vertical contact trenches 400a may open at least a portion of the second gate layer 370 or at least a portion of the second test gate layer 370t.

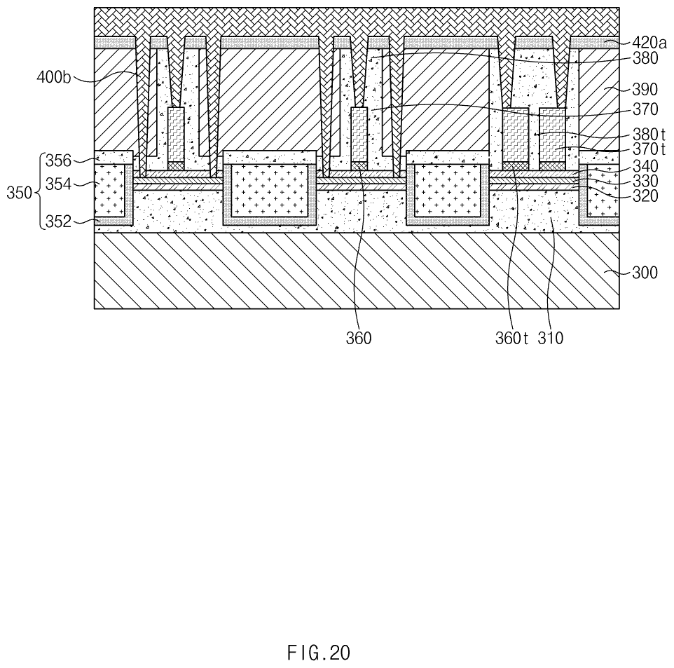

Referring to FIG. 20, a first pre-vertical contact element 400b may be formed (e.g., by deposition) within the first pre-vertical contact element trench 400a of FIG. 19. The first pre-vertical contact element 400b may include a conductive material. For example, the first pre-vertical contact element 400b may include a metal or a metal nitride such as tungsten or titanium nitride.

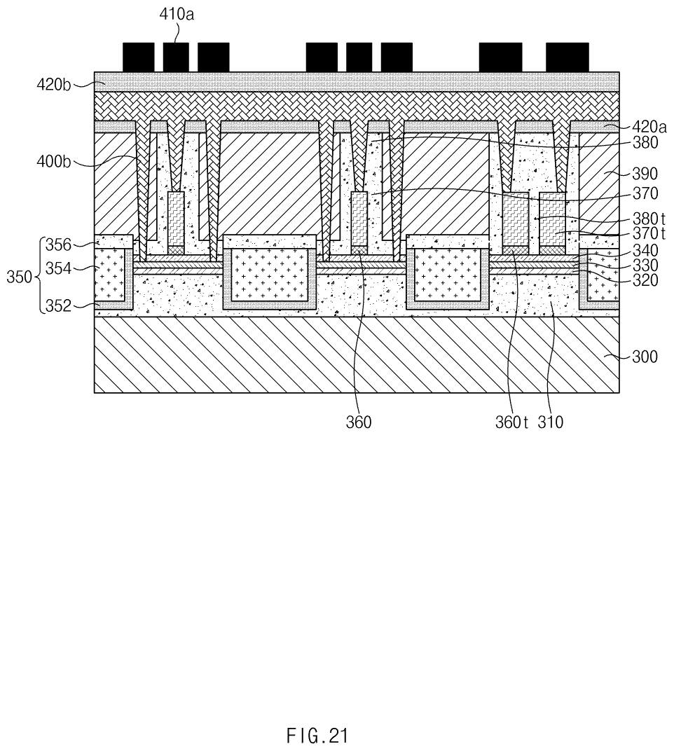

Referring to FIG. 21, an upper portion 420b of a second interlayer insulation layer may be formed on the first pre-vertical contact element 400b, and a first interconnect portion mask 410a may be formed on an upper portion 420b of the second interlayer insulation layer.

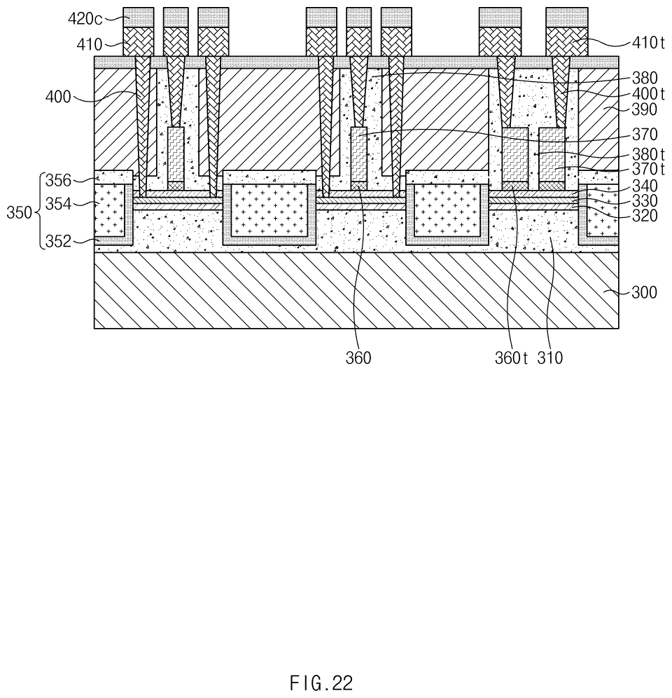

Referring to FIG. 22, at least a portion of the first pre-vertical contact element 400b and at least a portion of the upper portion 420b of the second interlayer insulation layer may be etched according to the shape of the first interconnect portion mask 410a of FIG. 21 to form the first interconnect portions 410.

In addition, the upper portions 420b of the second interlayer insulation layer remaining after being etched may be referred to as a residual insulation layer 420c.

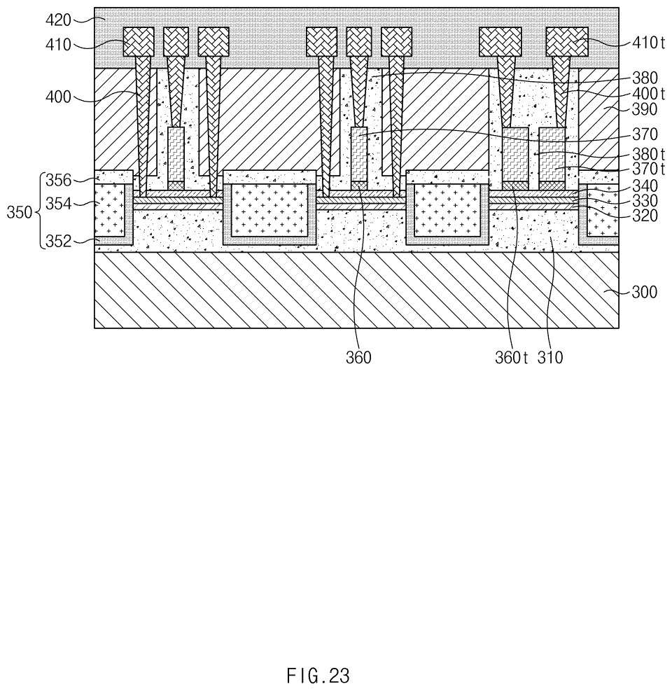

Referring to FIG. 23, first interconnect portions 410 and first test interconnect portions 410t may be formed within second interlayer insulation layer 420. After the upper portions 420b of the second interlayer insulation layer are etched using the first interconnect portion mask 410a, the second interlayer insulation layer 420 may be formed by depositing silicon nitride. The first interconnect portions 410 or the first test interconnect portions 410t adjacent to each other may be electrically isolated from each other by the second interlayer insulation layer 420.

In the embodiment of FIG. 21, the first test interconnect portions 410t may be used as connection portions between the first test vertical contact elements 400t and second test vertical contact elements to be formed later. In the embodiment of FIG. 21, a pair of a first test gate layer 360t and a second test gate layer 370t adjacent to each other may be referred to as a pair of test gates (hereinafter referred to as a test gate pair).

A test gate insulation layer 380t disposed between the test gate pair (360t, 370t) may include the same material as the gate insulation layer 380, and may be formed through the same deposition process, so that the hydrogen passivation influence on the gate insulation layer 380 may be confirmed by detecting the breakdown voltage of the test gate insulation layer 380t.

As is apparent from the above description, the semiconductor device based on some embodiments of the present disclosure may include a test pattern disposed in a target insulation layer, which is a target of confirmation of a breakdown voltage, from among a plurality of insulation layers included in the semiconductor device.

According to embodiments of the present disclosure, the test pattern may have a metal-insulation layer-metal structure, and the target insulation layer may be disposed between interconnect portions including metal. As a result, a breakdown voltage, which is a voltage at which a test current greater than a threshold current (critical current) flows when the target insulation layer breaks down, may be detected.

The embodiments of the present disclosure may provide a variety of advantageous effects capable of being directly or indirectly recognized.

Those skilled in the art will appreciate that the embodiments of the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present disclosure. Furthermore, the embodiments may be combined to form additional embodiments,

What is claimed is:

1. A semiconductor device comprising:
a target insulation layer shared by a transistor pattern disposed in a first region and a test pattern disposed in a second region,
wherein the test pattern includes detection interconnect elements disposed within the target insulation layer, and
wherein the test pattern outputs a test current corresponding to a test voltage provided through the detection interconnect elements.

2. The semiconductor device according to claim 1, wherein at least a portion of the target insulation layer is disposed between the detection interconnect elements.

3. The semiconductor device according to claim 1, wherein the test pattern is electrically isolated from the transistor pattern.

4. The semiconductor device according to claim 1, wherein the target insulation layer includes silicon nitride.

5. The semiconductor device according to claim 1, wherein the detection interconnect elements are respectively connected to vertical contact elements, and a width between the detection interconnect elements is narrower than a width between the vertical contact elements.

6. The semiconductor device according to claim 5, wherein the vertical contact elements are respectively connected to interconnect portions, and the width between the detection interconnect elements is narrower than the width between the interconnect portions.

7. The semiconductor device according to claim 1, wherein the target insulation layer is passivated by hydrogen.

8. The semiconductor device according to claim 1, wherein the target insulation layer prevents hydrogen from flowing into a lower region.

9. The semiconductor device according to claim 8, wherein the lower region is disposed in the first region and includes a channel region of the transistor pattern.

10. The semiconductor device according to claim 9, wherein the channel region includes an oxide semiconductor material.

11. The semiconductor device according to claim 1, wherein the detection interconnect elements include a metal material.

12. A semiconductor device comprising:
a first region in which a plurality of transistor patterns is disposed;
a second region in which a plurality of test patterns is disposed; and
a plurality of insulation layers disposed across the first region and the second region,
wherein one of the plurality of test patterns includes:
detection interconnect elements disposed in a target insulation layer among the plurality of insulation layers; and
vertical contact elements disposed in another insulation layer contacting the target insulation layer, and
wherein a width between the detection interconnection elements is narrower than a width between the vertical contact elements.

13. The semiconductor device according to claim 12, wherein at least a portion of the target insulation layer is disposed between the detection interconnect elements.

14. The semiconductor device according to claim 12, wherein one of the plurality of test patterns outputs a test current corresponding to a received test voltage.

15. The semiconductor device according to claim 12, wherein the plurality of test patterns is configured to use different insulation layers among the plurality of insulation layers as target insulation layers.

16. The semiconductor device according to claim 12, wherein the detection interconnect elements and the vertical contact elements include a conductive material.

17. The semiconductor device according to claim 12, wherein one of the plurality of test patterns further includes:
interconnect portions that are connected to the vertical contact elements and are disposed in an insulation layer different from the target insulation layer, and
wherein a width between the detection interconnect elements is narrower than a width between the interconnect portions.

18. The semiconductor device according to claim 17, wherein the interconnect portions included in one of the plurality of test patterns are disposed on the same insulation layer as the detection interconnect elements included in another one of the plurality of test patterns.

19. A semiconductor device comprising:
a transistor pattern disposed in a first region;
a test pattern disposed in a second region and including detection interconnect elements disposed within a target insulation layer,
wherein the test pattern outputs a test current corresponding to a test voltage provided through the detection interconnect elements, and
wherein the test pattern is electrically isolated from the transistor pattern.
